(19) United States
(12) Patent Application Publication
(10) Pub. No.: US 2022/0319900 A1
(43) Pub. Date: Oct. 6, 2022

(54) SELECTIVE DONOR PLATES, METHODS OF FABRICATION AND USES THEREOF FOR ASSEMBLING COMPONENTS ONTO SUBSTRATES

(71) Applicant: Terecircuits Corporation, Mountain View, CA (US)

(72) Inventor: Jayna Sheats, Palo Alto, CA (US)

(21) Appl. No.: 17/657,242

(22) Filed: Mar. 30, 2022

Related U.S. Application Data
(60) Provisional application No. 63/169,651, filed on Apr. 1, 2021.

(51) Int. Cl. H01L 21/683; H01L 33/00

(52) U.S. Cl. CPC H01L 21/6835; H01L 33/0093; H01L 2221/68318

(57) ABSTRACT

Selective donor plates comprising at least one raised “mesa” and a release layer disposed over the top mesa surface are described, as well as their methods of use and their methods of fabrication. The use of selective donor plates including mesas and a release layer may enable reduced standoff distances and misplacement of components, as well as improve assembly time of devices.

### INCORPORATION BY REFERENCE TO ANY PRIORITY APPLICATIONS

Any and all applications for which a foreign or domestic priority claim is identified in the Application Data Sheet or Request as filed with the present application are hereby incorporated by reference under 37 CFR 1.57, and Rules 4.18 and 20.6. U.S. Provisional App. No. 63/169,651, filed Apr. 1, 2021, is hereby incorporated by reference in its entirety.

### BACKGROUND

### Field

This invention pertains to devices which are fabricated using photoactivated thermal transfer elements.

### Description of the Related Art

U.S. Pat. Nos. 6,946,178 and 7,141,348, each of which are hereby incorporated by reference in their entirety for all purposes, disclose methods of transferring, or printing, thin film devices from a donor substrate (i.e., “donor plate”), on which the polymeric photoactivated thermal transfer material has been applied in a thin film, onto a target substrate.

Many techniques have recently been used for processing microelectronics, such as serial pick-and-place, laser ablation, stamps and adhesives. However, improved techniques for transferring a selection of components may be beneficial.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

In one aspect, a selective donor plate is described. The selective donor plate comprises: a donor plate substrate comprising a donor plate surface; a mesa disposed over the donor plate substrate and adjacent to the donor plate surface; and a release layer disposed over the mesa.

In some embodiments, the selective donor plate comprises a plurality of mesas. In some embodiments, a first set of the plurality of mesas comprise a first height and a second set of the plurality of mesas comprise a second height, wherein the first height is different than the second height. In some embodiments, the donor plate further comprises a component disposed over the mesa and release layer. In some embodiments, an area of the mesa is smaller than an area of the component.

In another aspect, a process of using a selective donor plate is described. The process comprises: positioning a selective donor plate at a standoff distance over a receiving substrate comprising a target location, wherein the component is aligned with the target location; decomposing the release layer; and depositing the component onto at least a portion of the target location of the receiving substrate, wherein a portion of the component outside of the target location is a misplacement.

In some embodiments, the misplacement is at most about 100 nm. In some embodiments, the standoff distance is at most about 3 μm. In some embodiments, the receiving substrate further comprises previously deposited components. In some embodiments, the selective donor plate comprises a plurality of components, and wherein the plurality of components are deposited simultaneously onto the receiving substrate. In some embodiments, the process further comprises depositing an additional release layer onto the mesa subsequent to decomposing the release layer. In some embodiments, the process further comprises loading the mesa with the component from a source substrate. In some embodiments, the source substrate further comprises an additional component, wherein loading comprises contacting the release layer to the component, and wherein the additional component is not loaded onto the selective donor plate. In some embodiments, the process further comprises forming a device from the receiving substrate, wherein the device is selected from the group consisting of a light emitting diode (LED), a thin film sensor, a microelectromechanical systems (MEM) device, a thin film capacitor, a thin film resistor, and combinations thereof. In some embodiments, the device is an LED.

In another aspect, a process of fabricating a selective donor plate is described. The process comprises: forming a mesa on a surface of a donor plate, wherein the mesa comprises a surface; and depositing a release layer over the surface of the mesa.

In some embodiments, forming the mesa comprises depositing a material on the surface of the donor plate. In some embodiments, forming the mesa comprises etching the surface of the donor plate. In some embodiments, the selective donor plate comprises a donor plate substrate surface, wherein depositing the release layer further comprises depositing the release layer over the donor plate substrate surface. In some embodiments, the process comprises forming a plurality of mesas.

### BRIEF DESCRIPTION OF THE DRAWINGS

These and other features, aspects, and advantages of the present disclosure are described with reference to the drawings of certain embodiments, which are intended to illustrate certain embodiments and not to limit the invention. For example, the drawings and/or elements depicted within the drawings may not be drawn to scale.

FIG. 1 is an illustration of a titled chip released from a donor plate.

FIGS. 2A-2E illustrate a process of depositing multiple sets of components onto a receiving substrate from a donor plate comprising a release layer, according to some embodiments.

FIG. 3 is an illustration of a PCA process for depositing components from a donor plate to a substrate, wherein the donor plate has a uniform surface.

FIG. 4 is an illustration of a selective donor plate and a process for depositing components from the selective donor plate to a substrate from mesas on the donor plate surface, according to some embodiments.

### DETAILED DESCRIPTION

Although certain embodiments and examples are described below, those of skill in the art will appreciate that the invention extends beyond the specifically disclosed embodiments and/or uses and obvious modifications and equivalents thereof. Thus, it is intended that the scope of the invention herein disclosed should not be limited by any particular embodiments described below.

Selective donor plates with raised sections are provided, wherein the raised sections may be referred to as “mesas.” The release layer may be disposed over at least the surfaces of the mesas of the selective donor plate. The raised mesas with the release layer may be contacted with a component to load (e.g., pick up), the loaded selective donor plate may be aligned with a receiving substrate, and once the release layer is degraded the components are received by the receiving substrate. The mesas may allow reduced standoff distances and/or minimize placement errors between the surface of the component and the receiving substrate surface. The mesas may also allow for selective loading of components onto the selective donor plate when the raised mesas are contacted with the component from a source substrate (e.g., source wafer). Methods of fabricating the selective donor plate and mesas are also described.

In the processes described in U.S. Pat. Nos. 6,946,178 and 7,141,348, each incorporated by reference in their entirety for all purposes, irradiation with actinic light is used to selectively activate a release layer (e.g., comprising a polymer) under a component or device which the user wishes to transfer, while leaving other components or devices on the same substrate unactivated. Heating the release layer (e.g., comprising a release material that comprises a polymer) (also referred to as a digital release material (e.g., digital release adhesive (“DRA”))), causes the release layer to vaporize and transfer the component or device to a target substrate in close proximity while leaving the unactivated components or devices on the donor substrate. By this method, such components or objects (e.g., integrated circuit chips with lateral dimensions of less than 100 μm) that are difficult or impossible to handle effectively by other means (e.g., pick and place machines which are well known in the art) can be placed onto product substrates at high speed. Such a described process, which may be referred to as Photopolymer Component Assembly (“PCA”) or Light-Induced Forward Transfer (“LIFT”) may be used for small and/or thin components (e.g., silicon chips), and may also be used with any object which is thin enough to be readily adhered to a thin release layer (e.g., polymer) film; for example such as light emitting diodes (LEDs), thin film sensors, microelectromechanical systems (MEMS) devices, thin film capacitors or resistors, any semiconductor device or component, and other electronic, optical or mechanical components.

Precision transfer in some instances depends at least in part on the uniformity of the chemical reaction which decomposes the release layer (e.g., photoactive polymer film). If some areas of the film decompose to vapor while other areas remain solid, the component previously being held by the release layer may become tilted relative to the substrate even after the more slowly reacting release layer (e.g., polymer) decomposes, and the component will move to the substrate along a trajectory that includes this tilt. As such, the landing or resting point of the released and tilted component may not be the intended location on the receiving substrate. Such non-uniform decomposition may also give rise to rotation of the component, for example which may occur if vapor escapes from the decomposed release layer with an asymmetric lateral velocity. Thus, important aspects of a PCA process include the achievement of a high degree of uniformity in the release layer or DRA film thickness and the irradiance profile, both of which are factors in determining the uniformity and rate of the decomposition reaction. Control of the escape path, pressure and velocity of the vapor resulting from the decomposition of the release layer is also useful in controlling the release of the component. In some instances, the vapor at or near the component edges may escape more quickly than that which is near the center, which may potentially result in uneven forces on the component.

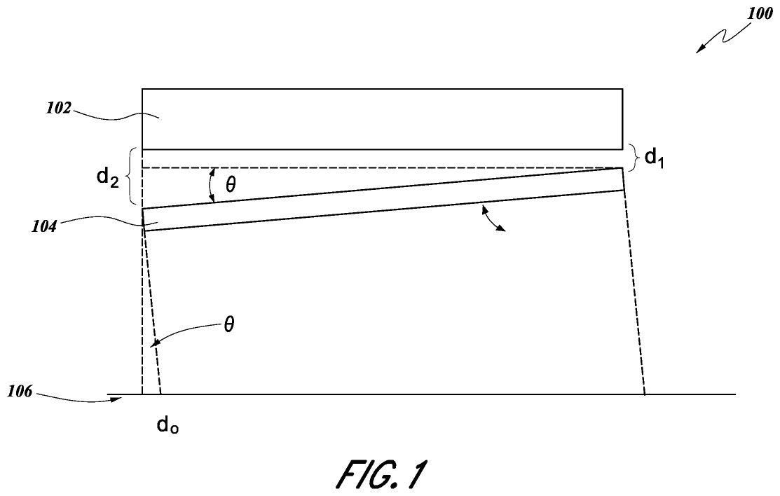

Another factor that may affect placement and/or precision of a released component is the standoff distance, which is the distance from the outer surface of a component to the receiving surface. Generally, the larger or further the standoff distance the greater the absolute amount of placement error from a target location, as illustrated in FIG. 1 showing the lateral misplacement effects during a PCA process. Assembly 100 depicts distances d₁ and d₂ as the distances between the top surface of a chip or component 104 from a bottom surface of a donor plate 102 at proximal and distal ends of the donor plate. As component 104 is tilted at angle θ, d₁ is smaller than d₂. This difference (d₂−d₁), which may be denoted as d_{δ}, results in a misplacement dₒ from a target location when the component 104 lands on substrate 106. From geometry tan θ=d_{δ}/w, where w is the width of the chip. Under the assumption the component 104 (e.g., chip) travels in a straight line after this initial misalignment, tan θ=dₒ/h, where h is the standoff distance between the component 104 (e.g., chip) and the substrate 106. The misplacement is thus seen to be a function of h, where dₒ=dδ(h/w). Thus it is desirable to minimize standoff distance h in order to minimize misplacement dₒ.

In typical PCA processes, when the first component, or set of components is placed on a receiving surface the donor plate can be brought to a relatively close standoff distance to the substrate. The closeness of the components to the receiving surface may be limited by the variation in flatness of the surfaces of the DRA film and components, which in sum can be of the order of a micrometer or less. With a comfortable process latitude and taking into account this variation the standoff distance may, for example, be set to about 3 μm. However, after the first component, or set of components, is placed on the receiving surface, the standoff distance must include allowance for the component(s) that is already present on the receiving surface. For example, if the first component placed has a height of 5 μm, then the standoff for second and succeeding placements may be 8 μm.

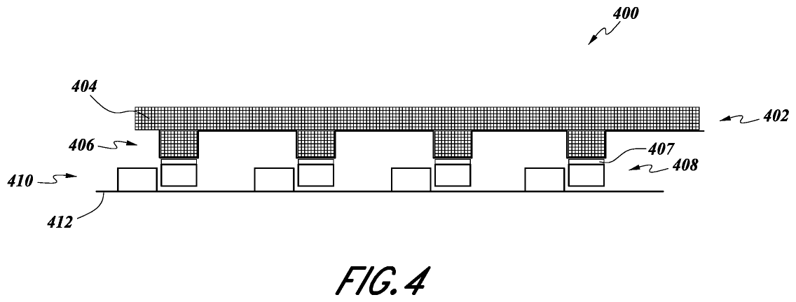

In some embodiments, one of the objects herein is to provide a selective donor plate with raised mesa sections that are configured to minimize placement error. In some embodiments, the surface area of the mesa is larger than, the same as, or smaller than the area of a surface of the component to be transferred. The release layer may be applied to at least the top surfaces of the mesas of the selective donor plate. In some embodiments, the mesa comprises a raised top surface and side walls disposed over the donor plate substrate. In some embodiments, the top surface of the mesa is or is substantially parallel (e.g., flat) to the surface of the donor plate substrate. In some embodiments, the top surface of the mesa is or is substantially parallel (e.g., flat) relative to the surface of the source substrate and/or receiving substrate. In some embodiments, the side walls of the mesa are or are substantially perpendicular (e.g., flat) or angled (e.g., acute or obtuse) relative to the surface of the donor plate substrate. In some embodiments, the side walls of the mesa are or are substantially concave or convex. In some embodiments, the side walls of the mesa raise the top surface of the mesa above the donor plate surface by a mesa height. In some embodiments, the mesa height is or is about the height of a component (e.g., a loaded component and/or a previously deposited component). In some embodiments, the mesa height is, is about, is at least, or is at least about, 0.05 μm, 0.1 μm, 0.5 μm, 0.8 μm, 1 μm, 1.5 μm, 2 μm, 2.5 μm, 3 μm, 3.5 μm, 4 μm, 4.5 μm, 5 μm, 5.5 μm, 6 μm, 7 μm, 8 μm, 9 μm, 10 μm, 15 μm or 20 μm, or any range of values therebetween. The selective donor plate may include one mesa, at least one mesa or a plurality of mesas. In some embodiments, the selective donor plate may include mesas with similar relative sizes (e.g., area, length, width, height and/or thickness) and/or shapes. In some embodiments one or more sets of mesas may be formed with different (e.g., larger or smaller) relative sizes (e.g., area, length, width, height and/or thickness) and/or different shapes than that of another set of mesas. FIG. 4 depicts an embodiment with a selective donor plate with a plurality of mesas, and it is understood that FIG. 4 is for illustrative purposes and may not be drawn to scale.

Before bringing the selective donor plate with release layer coated mesas into contact with a source wafer or plate, in some embodiments the mesas are aligned to the components of the source wafer so that each mesa picks up the components. In some embodiments, the edges of the components are aligned to the edges of the mesa. In some embodiments, the edges of the mesa need not be directly above the component edges, for example if the surface of the mesa is smaller than the surface of the component. In some embodiments, alignment of the components and the mesa occurs when the edges of the mesa are directly above the component edges. In some embodiments, alignment of the components and the mesa occurs when the edges of the mesa are encompassed by the component edges. In some embodiments, alignment of the components and the mesa occurs when the edges of the component are encompassed by the mesa edges.

In some embodiments, another object of the selective donor plate with raised mesa sections is to selectively load components onto the mesas of the selective donor plate from a source substrate (e.g., source wafer). As the mesas are raised above the surface of the substrate of the donor plate, the mesas comprising a release layer coated onto the surface of the mesa are able to selectively load a selection of components from a source substrate, while leaving non-selected components behind on the source substrate. In some embodiments, the selective donor plate is loaded by bringing the release layer of the mesas into contact with components from a source substrate. In some embodiments, the selective donor plate is loaded by depositing components from a source substrate onto the release layer of the mesas.

In some embodiments, once the selective donor plate is loaded with components at the locations of the mesas, the donor plate is moved to a main transfer printer and aligned to a receiving substrate, and/or the mesas and/or loaded components are aligned to target locations of the receiving substrate. In some embodiments, the mesas are aligned to the intended receiving areas of the receiving substrate for the components. When the component on the mesa of the selective donor plate is lowered into near proximity with the receiving substrate surface (e.g. within 3 μm as was used for the first placement), the remainder of non-raised surfaces of the selective donor plate do not make contact with (e.g., touch) or require additional clearance for components already positioned on or previously deposited onto the receiving substrate because the mesas provide additional clearance. Therefore, in some embodiments, standoff distance and/or misplacement of deposited components may be reduced relative to that of donor plates without mesas.

The use of such geometry of selective donor plates comprising mesas and release layers may improve one of the advantages of the PCA process, especially in comparison to competitive methods of placing components for microelectronics. For example, U.S. Pat. No. 7,799,699 discloses methods of placing thin semiconductor devices using a polymeric stamp, which has mesa-like structures. In that process, the stamp is used to pick up components on the raised portions of the stamp, move them to a substrate, and deposit them on the substrate by peeling the stamp back in such a way that the adhesion of the components to the substrate is greater than their adhesion to the stamp. Such a stamp must pick up a component on every raised mesa (but not more than that), move from the source position to the substrate position, and then deposit all loaded components on the substrate at once. By contrast, the process disclosed in U.S. Pat. Nos. 6,946,178 and 7,141,348 allows picking up all of the components on a source wafer or plate (including, for example, all of the chips from a 300 mm diameter semiconductor wafer), and then positioning all of them over a substrate. A subset of chips which one may wish to deposit onto a substrate can be selected by an applied optical irradiation pattern, and then a new subset can be transferred to a new substrate with very little motion of the donor plate. This reduces the amount of motion required of the machine and makes the process faster.

For example, consider the fabrication of wireless sensor circuits, which in some instances are composed of a microprocessor, a radio, a sensor, and a few passive components (capacitors and resistors). The total area of the circuit may be of the order of 2×2 cm to accommodate a suitable rf antenna, and the placement process must deposit one chip of each type onto each one of the 2×2 cm areas of a substrate. The substrate may be 20×20 cm, for example (to be easily handled by common semiconductor process equipment), and so will contain 100 units. These chips (e.g. small microprocessors, suitable for simple sensor control functions) could have an area of 1×1 mm or less, in which case a 300 mm diameter wafer would contain approximately 70,000 chips. The donor plate for the PCA process will hold all 70,000, and this plate need not be removed or replenished until 700 substrates have been processed. Smaller chips lead to even larger ratios of this type.

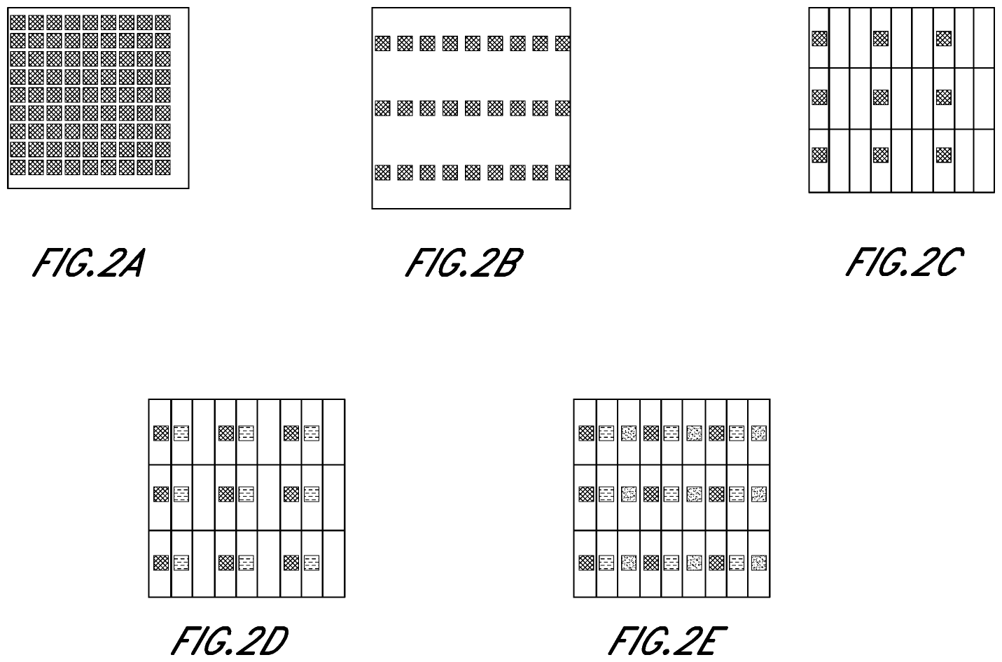

In some embodiments, the advantage of the typical donor plate PCA process, relative to the stamp transfer, when using selective donor plates may be reduced because the presence of the mesas in some instances may reduce the number of components that may be loaded to the selective donor plate, and therefore in some instances the number of movements from source to target may be increased when using selective donor plates (e.g., the same for both the stamp transfer and selective donor plate methods). However, the small spacing of components in some architectures (e.g., LEDs in microdisplays) may diminish or negate any such disadvantages for selective donor plates, and may provide additional advantages for using selective donor plates. In some instances, components (e.g., LED chips) may be deposited in arrays with separations of the order of tens of microns (e.g., 20-30 μm). For example, an LED display with 800 pixels per inch would have a pixel periodicity of 31.25 μm, within which there are three LEDs (red, green and blue) on 10.42 μm centers. Each of the LEDs may be a different size according to their optimum fabrication conditions, and is typically as small as possible to minimize cost. For a micro-display suited for augmented reality or virtual reality displays, the array may be 1100 or more pixels per inch, wherein 1100 pixels per inch corresponds to a period of 22.73 μm, and subpixel period of 7.58 μm. An illustration of one type of display with these dimensions is shown in FIGS. 2A-2E.

FIGS. 2A-2E illustrates an embodiment of a transfer process for depositing multiple sets of components onto a receiving substrate from donor plates comprising a release layer. For example, the process shown in FIGS. 2A-2E may be used to form LED micro-displays. FIG. 2A shows square components (e.g., LEDs that have been diced) on source substrate (e.g., source array). Moving from FIG. 2A to FIG. 2B, the components are transferred from the source substrate (e.g., source array) and redistributed on an intermediate donor plate comprising a release layer as shown in FIG. 2B. In some embodiments, the components shown in FIG. 2B have a larger spatial period relative to the corresponding source substrate the components are sourced from. In some embodiments, the spatial period of the components shown in FIG. 2B will precisely or substantially match the spatial period of the device (e.g., display) or receiving substrate they are destined for. In some embodiments, as shown in FIG. 2B, the spatial period of components is greater in the vertical direction than the horizontal direction. In some embodiments, the spatial period of components is greater in the horizontal direction than the vertical direction (e.g., where LED pixels are square with rectangular sub-pixels). During transfer of the components from source substrate of FIG. 2A to the intermediate donor plate of FIG. 2B, all of the components (e.g., chips) are in the same plane and the standoff required is very small (e.g. about 1 μm). In some embodiments, the intermediate donor plate shown in FIG. 2B is a selective donor plate. Moving from FIG. 2B to FIG. 2C, select components (e.g., red LEDs) are transferred (e.g., moved or picked up) simultaneously from the intermediate donor plate to a selective donor plate which has mesas distributed, and then the select components disposed over the mesas are deposited from the selective donor plate to a receiving substrate. In some embodiments, the select component distribution or pattern of the select donor plate is the same, substantially the same, similar to or substantially similar to that of the receiving substrate. In some embodiments, FIG. 2C depicts the selective donor plate loaded with select components. In some embodiments, FIG. 2C depicts the receiving substrate after receiving the select components from the selective donor plate. The steps shown in FIGS. 2A-2C may be repeated with a second and then third substrate put in position and a second and then third mesa-equipped selective donor plate bringing a second array or set of components (e.g., green LEDs or chips) and then third array or set of components (e.g., blue LEDs or chips) to the receiving substrate in the same or similar fashion to deposit a second set and then third set of components on the receiving substrate shown in FIG. 2C to form the second receiving substrate shown in FIG. 2D, and then form the third receiving substrate shown in FIG. 2E. After the select components of intermediate donor plate shown in FIG. 2B are removed by a selective mesa, the intermediate donor plate may still contain components that may be transferred to a selective mesa from transfer to other receiving substrates until it is empty of components. A new intermediate donor plate may then be provided and may contain the same components (e.g., the same color LED for a new receiving substrate), or different components (e.g., a different color LED to complete the assembly the first or subsequent receiving substrates).

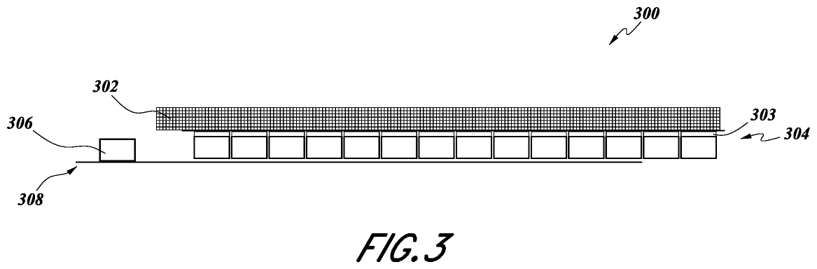

As an example, it may be common for displays to have approximately the same number of pixels in the horizontal and vertical directions, though this may not always be the case. In examples where pixels are square, the chips which may initially be of the order of 5×5 μm, with nominally 1 μm dicing streets between them, which must first be redistributed to a period of 7.58 μm (or 10.42 μm), which is ⅓ of the pixel periodicity, similar to the illustration of FIG. 2B. In some embodiments, such a display may be accomplished by using a PCA process, as illustrated in FIG. 3.

FIG. 3 illustrates a PCA process 300 for depositing components from a donor plate 302 to a substrate 308, wherein a side cross-sectional view of a first transfer step in which components (e.g., chips) from one wafer are redistributed to the desired spacing on an intermediate donor plate is shown (e.g., FIG. 2A to FIG. 2B). In some embodiments, the process of FIG. 3 is performed twice, for example once in each orthogonal direction so the resulting intercomponent (e.g., interchip) spacing may be different in the two directions as necessary. FIG. 3 shows a first row of components (e.g., chips) 306 already placed on the substrate 308 and a plurality of rows of components 304 attached to the donor plate 302 by a release layer 303 (e.g., approximately 1 μm thick DRA layer), wherein the component row of the plurality of rows of components 304 proximal to the first row of components 306 is spaced apart from the first row of components 306 and positioned over the location substrate 308 where it is intended to be deposited. The other rows of components, aside from the component row of the plurality of rows of components 304 proximal to the first row of components 306, are not intended to be transferred to the substrate 308 until the donor plate is moved to the right or the substrate is moved to the left. Because the transfer of each row of components is carried out and advanced one row at a time across the substrate 308, the standoff distance between the bottom surface of each component and the top surface of the substrate 308 can be maintained at the same or similar minimum value.

However, once the original array of components has been redistributed, a mesa-structured selective donor plate disclosed here may be advantageously used to pick up a sub-array of components and transfer or deposit the sub-array of components onto a receiving substrate (e.g., one LED per pixel), for example as illustrated in FIG. 2C and subsequently in FIGS. 2D and 2E. For example, with the utilization of a selective donor plate a component (e.g., an LED) from each row and from every third column as depicted in FIG. 2C would be loaded to the selective donor plate and subsequently simultaneously transferred (e.g., deposited) to a receiving substrate in each operation, thus reducing the number of cycles or trips from source or intermediate donor plate to target or receiving substrate by 3 relative to a process where a donor plate without mesas is used (e.g., the process described for FIG. 3). While such a process utilizing selective donor plates may add some mechanical overhead, such a process greatly reduces the component misalignment and processing time relative to a process where a donor plate without mesas is used in which 700 or more trips may be involved, and therefore may provide substantial advantages that likely overcome any added complexity.

FIG. 4 illustrates a side cross-sectional view of a selective donor plate 402 comprising a donor plate substrate 404 and mesas 406 raised above the surface of the donor plate substrate 404, and a process 400 for depositing loaded components 408 from the mesas 406 of the selective donor plate 404 to a substrate 412 once the release layers 407 holding the loaded components 408 to the mesas 406 are degraded. FIG. 4 depicts previously deposited components 410 positioned on the substrate 412, and even so the selective donor plate 402 is able to bring the surfaces of loaded components 408 into close proximity with the surface of the substrate 412 due to the fact that the mesas 406 are disposed over the loaded components 408 and raised beyond the surface of the donor plate substrate 404. Although FIG. 4 depicts mesas with a similar size (e.g., area, length, width, height and/or thickness) and shape to the loaded components 408, in some embodiments mesas may be formed with different (e.g., larger or smaller) sizes (e.g., area, length, width, height and/or thickness) and/or a different shape than that of the loaded components. Although FIG. 4 depicts a plurality of mesas with similar relative sizes (e.g., area, length, width, height and/or thickness) and shapes, in some embodiments one or more sets of mesas may be formed with different (e.g., larger or smaller) relative sizes (e.g., area, length, width, height and/or thickness) and/or different shapes than that of another set of mesas. Although FIG. 4 depicts a plurality of mesas, in some embodiments the selective donor plate may comprise a mesa or at least one mesa. In some embodiments, the selective donor plate and/or process shown in FIG. 4 may be used to in the process shown in FIGS. 2A-2E (e.g., FIG. 2D). In some embodiments, the selective donor plate 402 comprising the loaded components 408 of FIG. 4 may be a cross sectional view of the device depicted in FIG. 2C. In some embodiments, the substrate 412 comprising the deposited components 410 of FIG. 4 may be a cross sectional view of the device depicted in FIG. 2C. In some embodiments, the selective donor plate 402 comprising the loaded components 408 and the substrate 412 comprising the deposited components 410 may each have a similar structure to the device depicted in FIG. 2C, and the selective donor plate 402 is positioned over the substrate 410 such that the loaded components 408 face the deposited components 410 as depicted in FIG. 4.

In some embodiments, the station holding the intermediate donor plate comprising the components (e.g., LEDs) in the expanded array periodicity (e.g., subpixel periodicity) is placed directly adjacent to the station holding the substrate. A feeder (e.g., a cassette feeder) feeds a release layer coated selective donor plate into the first station, where the selective donor plate is brought into contact or close proximity with the intermediate donor plate, which is irradiated with a dose of light and heat effective to cause transfer of the chips onto the mesas of the selective donor plate. In some embodiments, the transfer from the intermediate donor plate may be upwards or downward in the gravitational field. In some embodiments, the components (e.g., chips) are sandwiched between the surface of the intermediate donor plate and the surface of the mesas of the selective donor plate. In some embodiments, the surface of the intermediate donor plate, the surface of the mesas of the selective donor plate or a combination thereof is coated with a release layer (e.g., DRA). In some embodiments, substrate (e.g., intermediate donor plate, selective donor plate) that is the source of the components is irradiated to cause the release layer (e.g., DRA) to vaporize and leaving the chips deposited (e.g., adhered) to the other film. This process may advantageously be used with a co-pending application which provides pores or channels in the release layer for the escape of degraded release layer (e.g., DRA) vapors.

In some embodiments, once the selective donor plate is loaded with components, the populated or loaded mesa-structured selective donor plate may be raised (e.g., by several micrometers), moved laterally until over and aligned to a receiving substrate, and lowered again to within the desired standoff distance between the components and the surface of the receiving substrate. In some embodiments, the standoff distance may be a few micrometers (e.g., as illustrated in FIG. 4). In some embodiments, the standoff distance is, is about, is at most, or is at most about, 0.05 μm, 0.1 μm, 0.5 μm, 0.8 μm, 1 μm, 1.5 μm, 2 μm, 2.5 μm, 3 μm, 3.5 μm, 4 μm, 4.5 μm, 5 μm, 5.5 μm or 6 μm, or any range of values therebetween. In some embodiments, the standoff distance may be zero such that the components make contact with the substrate surface. Once a standoff distance is reached, the release layer is irradiated to releases the components (e.g., chips) from the selective donor plate onto the substrate. In some embodiments, as standoff distance may be reduced relative to typical donor plates, misalignment of the deposited component outside of a target location may be achieved. In some embodiments, the misalignment is, is about, is at most, or is at most about, 0 nm, 1 nm, 3 nm, 5 nm, 10 nm, 20 nm, 30 nm, 40 nm, 50 nm, 60 nm, 70 nm, 80 nm, 90 nm, 100 nm, 125 nm, 150 nm, 200 nm, 250 nm, 300 nm, 350 nm, 400 nm, 450 nm, 500 nm, 550 nm, 600 nm, 700 nm, 800 nm, 900 nm or 1 μm, or any range of values therebetween. In some embodiments, once components are deposited the selective donor plate may be raised and moved into a cassette to enter a process stream for cleaning, release layer (e.g., DRA) re-coating with an additional release layer and re-use (e.g., re-use as described herein). In some embodiments, a new donor plate (e.g., selective donor plate) may be moved in from an adjacent transfer station.

While the precise throughput of this system depends on many factors, an example estimate of the motion of plates from one station to another may take at most a few seconds (e.g., between 1 and 5 seconds), alignment a few seconds more (e.g., between 1 and 3 seconds), and the transfer requires less than 1 msec. In some embodiments, each operation places for example up to several million components (e.g., LEDs) simultaneously, making the throughput very attractive for commercial application.

While in some embodiments the disclosure is described in terms of 5×5 μm components (e.g., LEDs), it should be appreciated that other sizes and shapes, including rectangular or circular components, are within the scope of the disclosure, and the spacings were given for illustration.

The selective donor plate may be fabricated from a donor plate, for example from a donor plate comprising a flat or substantially flat receiving surface. In some embodiments, mesa(s) are formed on the donor plate. In some embodiments, a mesa is formed, at least one mesa is formed, or a plurality of mesas are formed. In some embodiments, a material is added to the receiving surface of the donor plate to form a mesa. In some embodiments, the material added is the same or similar to the donor plate material. In some embodiments, the material added is different than the donor plate material. In some embodiments, the donor plate surface is etched into to form a mesa. In some embodiments, a release layer is deposited over the surface of the mesa. In some embodiments, the release layer is further deposited on the side walls of the mesa. In some embodiments, the release layer is further deposited on the surface of the donor plate substrate.

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products. For example, any of the components for an energy storage system described herein can be provided separately, or integrated together (e.g., packaged together, or attached together) to form an energy storage system.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount, depending on the desired function or desired result.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

The headings provided herein, if any, are for convenience only and do not necessarily affect the scope or meaning of the devices and methods disclosed herein.

What is claimed is:

1. A selective donor plate, comprising:
a donor plate substrate comprising a donor plate surface;
a mesa disposed over the donor plate substrate and adjacent to the donor plate surface; and
a release layer disposed over the mesa.

2. The donor plate of claim 1, wherein the selective donor plate comprises a plurality of mesas.

3. The donor plate of claim 2, wherein a first set of the plurality of mesas comprise a first height and a second set of the plurality of mesas comprise a second height, wherein the first height is different than the second height.

4. The donor plate of claim 1, further comprising a component disposed over the mesa and release layer.

5. The donor plate of claim 4, wherein an area of the mesa is smaller than an area of the component.

6. A process of using a selective donor plate, comprising:
positioning the selective donor plate of claim 4 at a standoff distance over a receiving substrate comprising a target location, wherein the component is aligned with the target location;
decomposing the release layer; and
depositing the component onto at least a portion of the target location of the receiving substrate, wherein a portion of the component outside of the target location is a misplacement.

7. The process of claim 6, wherein the misplacement is at most about 100 nm.

8. The process of claim 6, wherein the standoff distance is at most about 3 μm.

9. The process of claim 6, wherein the receiving substrate further comprises previously deposited components.

10. The process of claim 6, wherein the selective donor plate comprises a plurality of components, and wherein the plurality of components are deposited simultaneously onto the receiving substrate.

11. The process of claim 6, further comprising depositing an additional release layer onto the mesa subsequent to decomposing the release layer.

12. The process of claim 6, further comprising loading the mesa with the component from a source substrate.

13. The process of claim 12, wherein the source substrate further comprises an additional component, wherein loading comprises contacting the release layer to the component, and wherein the additional component is not loaded onto the selective donor plate.

14. The process of claim 6, further comprising forming a device from the receiving substrate, wherein the device is selected from the group consisting of a light emitting diode (LED), a thin film sensor, a microelectromechanical systems (MEM) device, a thin film capacitor, a thin film resistor, and combinations thereof.

15. The process of claim 14, wherein the device is an LED.

16. A process of fabricating a selective donor plate, comprising:
forming a mesa on a surface of a donor plate, wherein the mesa comprises a surface; and
depositing a release layer over the surface of the mesa.

17. The process of claim 16, wherein forming the mesa comprises depositing a material on the surface of the donor plate.

18. The process of claim 16, wherein forming the mesa comprises etching the surface of the donor plate.

19. The process of claim 16, wherein the selective donor plate comprises a donor plate substrate surface, wherein depositing the release layer further comprises depositing the release layer over the donor plate substrate surface.

20. The process of claim 16, wherein the process comprises forming a plurality of mesas.
